(19) United States
(12) Patent Application Publication
(10) Pub. No.: US 2013/0042906 A1
(43) Pub. Date: Feb. 21, 2013

(54) QUANTUM-DOT SENSITIZED SOLAR CELL

(71) Applicant: Ming-Way LEE, Taichung City (TW)

(72) Inventor: Ming-Way LEE, Taichung City (TW)

(21) Appl. No.: 13/213,624

(22) Filed: Aug. 19, 2011

(51) Int. Cl. H01L 31/06

(52) U.S. Cl. 136/255; 977/774

(57) ABSTRACT

A quantum dot sensitized solar cell including an anode, a cathode and an electrolyte is provided. The anode includes a semiconductor electrode adsorbed with a plurality of quantum dots. The quantum dots have a broad light absorption range that covers the ultraviolet, visible and infrared regions. The broad absorption range increases the ability of light harvesting, and accordingly, leads to an improved conversion efficiency of the solar cell.

### FIELD OF THE INVENTION

The present invention relates to a solar cell and particularly to a quantum dot-sensitized solar cell (QDSSC).

### BACKGROUND OF THE INVENTION

Solar energy is a crucial technology for solving the problems of high petroleum prices and global warming. Solar energy can be harvested by various methods such as wind energy, hydroelectricity and photovoltaics. Currently, the most widely used photovoltaic devices are silicon-based solar cells, but their high cost remains a problem. Recently, dye-sensitized solar cells (DSSC) have been emerging as a low-cost alternative photovoltaic source. The key component of a DSSC is a photoanode consisting of a nanoporous TiO₂ film coated onto a transparent conductive oxide glass substrate (usually indium-doped tin oxide (ITO) or fluorine-doped tin oxide (FTO)). The TiO₂ nanoparticles are sensitized by adsorbing a monolayer of organic dye molecules onto their surface. Upon solar illumination, the photoexcited electrons of the dye molecules are injected into the conduction band (CB) of the TiO₂ nanoparticles, then injected into the FTO substrate, finally producing a photocurrent. The highest efficiency achieved to date by DSSCs has been about 11%. High efficiency is due to the three-dimensional nanoporous network of TiO₂ nanoparticles, which greatly increases the surface area for dye adsorption, in turn, enhancing light harvesting. The most commonly used organic dyes, N3 and N719, have large optical absorption coefficients in the visible range (350-700 nm), but small absorption coefficients in the infrared (IR). However, the solar spectrum covers the range of 0.3-2.5 μm, with about 70% of the photon flux being distributed beyond 700 nm. In other words, the dye wastes 70% of the solar energy. To improve efficiency in DSSCs, one needs to find new sensitizers with a broadband photoresponse, especially in the IR region. A successful option for broadband sensitizers is semiconductor (extremely thin layer) absorbers. Semiconductor quantum dots (QDs) have also been used as sensitizers. QDs have several advantages over organic dye sensitizers such as having tunable absorption bands, high extinction coefficients, and multiple electron-hole pair generation. The most extensively studied QD sensitizers are the cadmium chalcogenide systems: CdS and CdSe, which have absorption ranges of 350-700 nm. To improve efficiency, it is desirable to explore new types of QD sensitizers with broad absorption ranges extending into the IR region.

### SUMMARY OF THE INVENTION

The primary object of the present invention is to solve the problems of dye-sensitized solar cells that have small absorption coefficients in the infrared range.

The present invention is directed to a quantum dot sensitized solar cell (QDSSC), which contains quantum dots as a light sensitizer. The disclosure provides a QDSSC including an anode, a cathode, and an electrolyte between the anode and the cathode. The anode includes a semiconductor electrode and a plurality of quantum dots coupled to the semiconductor electrode. The quantum dots are made of a material selected from the group consisting of Ag₂S, Ag₂Se, CuₓS and CuₓSe and are distributed within the semiconductor electrode layer.

The QDs have a broad optical absorption range covers the UV, visible and IR of the solar spectrum, allowing enhanced absorption of the incident solar radiation. Accordingly, the power conversion efficiency of the solar cells is improved.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a cross-sectional view of a quantum dot sensitized solar cell according to a first embodiment of the disclosure.

FIG. 2A is a structural cross-sectional view of an anode in the first embodiment.

FIG. 2B illustrates a quantum dot coupled to a TiO₂ particle in the first embodiment.

FIG. 2C illustrates the core-shell structure of a quantum dot.

FIG. 3 is a diagram illustrating the synthesis process of quantum dots of the invention.

FIG. 4 illustrates the photocurrent-voltage of QDSSCs in Experiment 2.

FIG. 5 illustrates the quantum-efficiency spectra of QDSSCs with various quantum dots.

FIG. 6 illustrates the photovoltaic ranges of various quantum dots over the solar spectral range.

### DETAILED DESCRIPTION OF THE PREFERRED EMBODIMENT

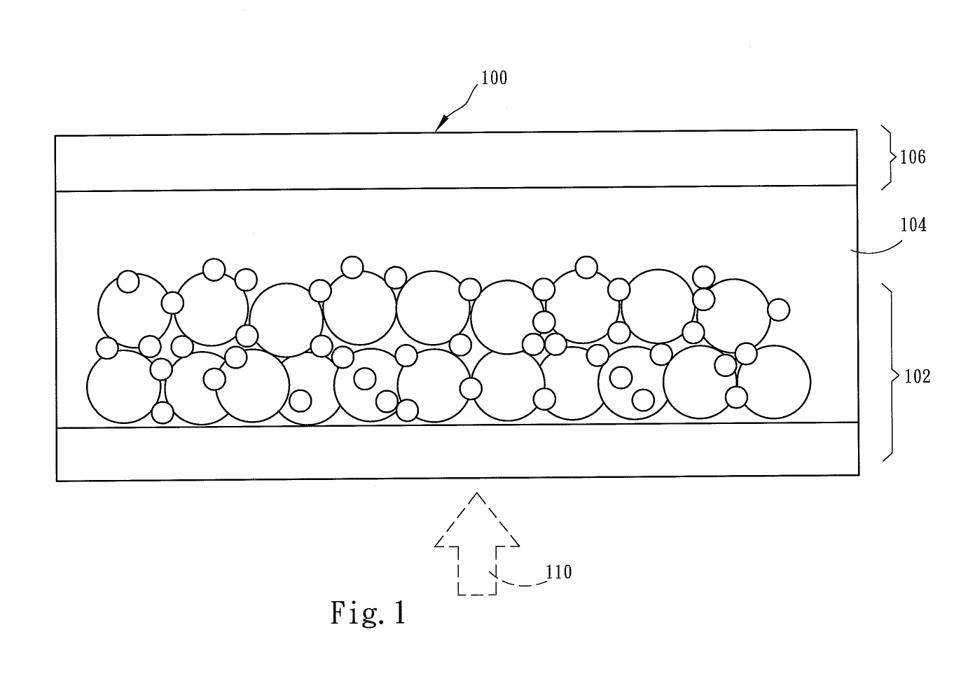

FIG. 1 is a cross-sectional view of a quantum dot sensitized solar cell according to a first embodiment of the disclosure. Referring to FIG. 1, in the present embodiment, the QDSSC 100 consists of an anode 102, a cathode 106, and an electrolyte 104 between the anode 102 and a cathode 106. An incident light 110 enters from the anode 102 side of the QDSSC 100.

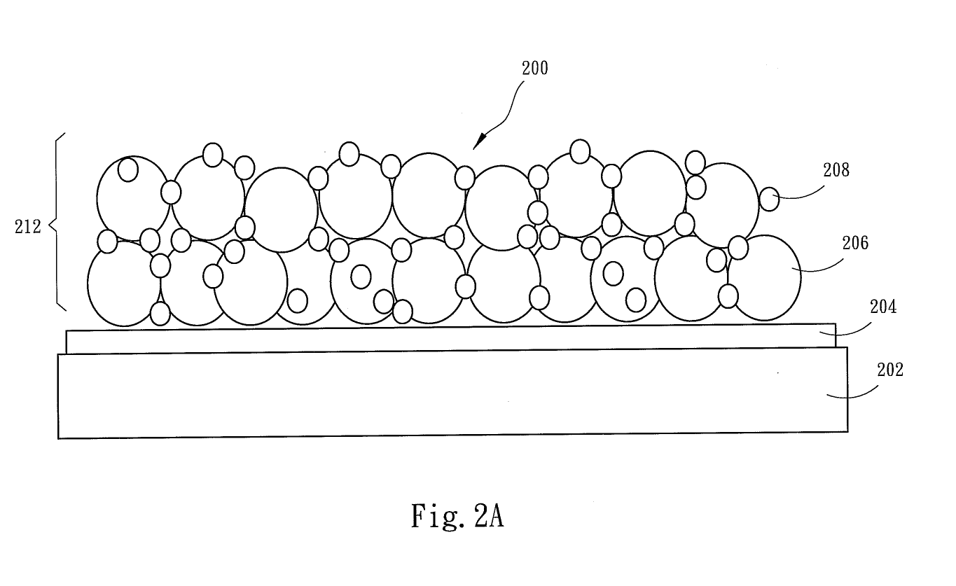

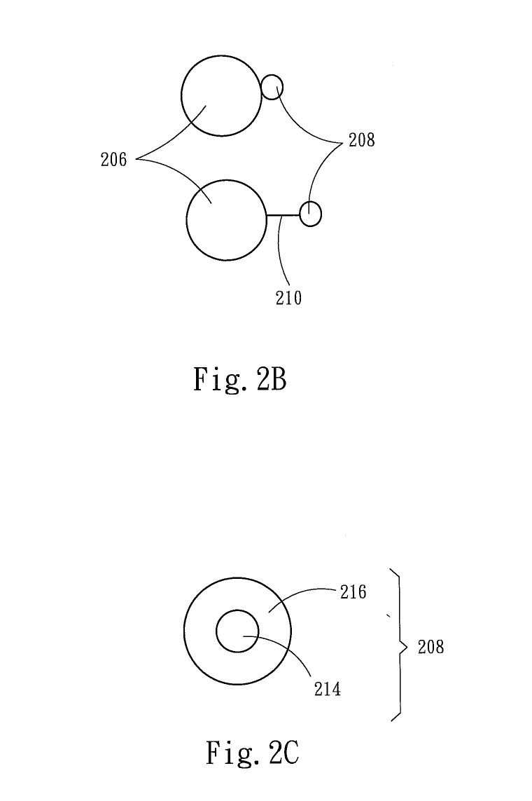

Referring to FIG. 2A, the anode 200 includes a semiconductor electrode layer 212 coated on a transparent conductive oxide (TCO) substrate 204. The transparent conductive oxide 204 can be made of materials of indium-doped tin oxide (ITO) or fluorine-doped tin oxide (FTO). The semiconductor electrode layer 212 comprises semiconductor electrodes 206, and a plurality of quantum dots 208 distributed within the semiconductor electrode layer 212, in other words, quantum dots 208 are deposited on the surface of the semiconductor electrode 206. A particle diameter of the quantum dots 208 is smaller than 20 nm. The materials of the semiconductor electrode layer 212 may be TiO₂, N-doped TiO₂ and ZnO. The shapes of the semiconductor materials may be nanoparticles, nanorods or nanotubes. In this embodiment, the quantum dots 208 could be Ag₂S, Ag₂Se, CuₓS or CuₓSe.

Referring to FIG. 2B, quantum dots 208 can be coupled directly to the surface of the TiO₂ particle of the semiconductor electrode 206. Alternatively, quantum dots 208 can be coupled to the semiconductor electrode 206 particle using a ligand linker 210.

Referring to FIG. 2C, a quantum dot 208 can have a core-shell or an inverse core-shell structure. In the core-shell structure the core material 214 can be Ag₂S, Ag₂Se, CuₓS or CuₓSe. The shell material 216 can be CdS, CdSe, CdTe, In₂S₃, In₂Se₃, In₂Te₃, PbS, PbSe, PbTe, SnS, SnSe, SnTe, Sb₂S₃, Sb₂Se₃, AlN, AlP, AlAs, GaN, GaP, GaAs, GaSb, InN, InP, InAs, InSb, Si or Ge.

In the inverse core-shell structure the shell material 216 can be Ag₂S, Ag₂Se, CuₓS or CuₓSe. The core material 214 can be CdS, CdSe, CdTe, In₂S₃, In₂Se₃, In₂Te₃, PbS, PbSe, PbTe, SnS, SnSe, SnTe, Sb₂S₃, Sb₂Se₃, AlN, AlP, AlAs, GaN, GaP, GaAs, GaSb, InN, InP, InAs, InSb, Si or Ge.

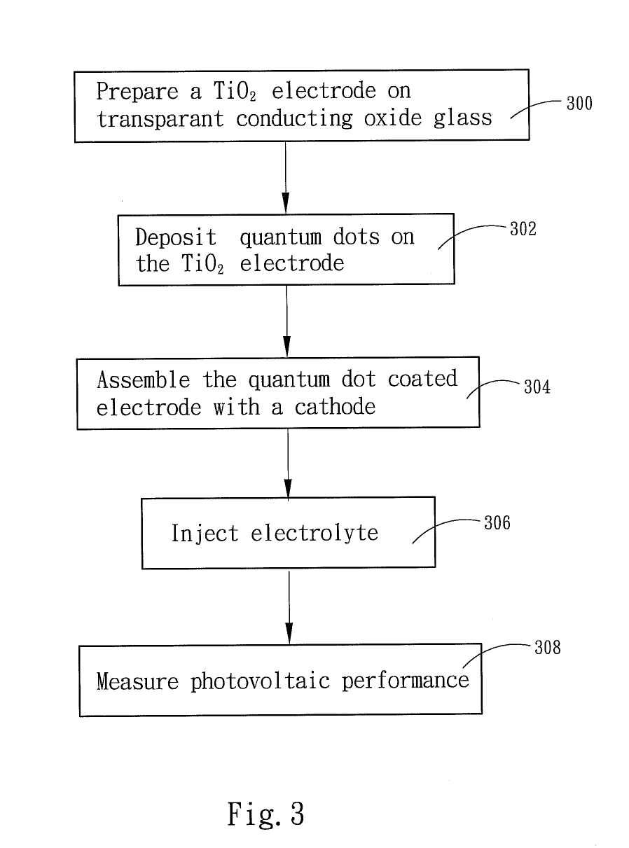

Also referring to FIG. 3, the present embodiment provides a series of processes for fabricating the QDSSC. First, step 300 is performed to fabricate a TiO₂ semiconductor electrode 206 on transparent conducting oxide glass. In step 302, quantum dots 208 are coated on the semiconductor electrode 206 using a sequential ion layer adsorption reaction (SILAR) process. In step 304, the quantum dot coated semiconductor electrode layer 212 is assembled with a cathode 106 into a solar cell. In step 306, an electrolyte 104 is injected into the assembled solar cell through two predrilled holes on the cathode 106. In step 308, measurements are carried out to study the photovoltaic performance, including photocurrent, voltage and power conversion efficiency, of the fabricated QDSSC 100.

Referring to FIG. 1, the cathode (or counterelectrode) 106 can be a TCO substrate coated with a thin layer of Pt film. The deposition of the Pt film can be performed with physical vapor deposition, magnetron sputtering deposition, or SILAR. The thickness of the Pt film is 2-4 nm. The electrolyte 104 can be a liquid-state electrolyte such as I⁻/I₃⁻ polyiodide, S⁻²/Sₓ⁻ polysulfide, or polycobolt liquid electrolyte. The electrolyte 104 can also be a solid-state electrolyte such as spirobifuorene.

Quantum dots 208 can be prepared using a chemical method such as the sequential ion layer adsorption reaction (SILAR) process. A precursor supplies the positive ions and a second precursor supplies the negative ions. A semiconductor electrode is sequentially dipped into the positive and negative ions. Repeated dipping produces quantum dots 208 on the semiconductor electrode 206.

### Experiment 1

### Fabrication of a Quantum Dot Sensitized Solar Cell

The steps are described as follows:

Step 1: Preparation of the TiO₂ electrode: An FTO glass substrate of resistivity 15Ω/□ is used as the substrate. A layer of TiO₂ of thickness about 12 μm is coated on the FTO glass using the doctor blade technique.

Step 2: The TiO₂ coated substrate is placed in a furnace and then heated at 500° C. for 50 min.

Step 3: Quantum dots are deposited onto the surface of the TiO₂ electrode using the SILAR process. The successive ionic layer adsorption and reaction deposition (SILAR) process for the growth of Ag₂S QDs is described as follows. First, a TiO₂ electrode was dipped into an AgNO₃ solution, washed with ethanol to obtain Ag⁺ ions. The electrode is subsequently dipped into a Na₂S solution to obtain S²⁻. The procedure produces Ag₂S QDs on the surface of the TiO₂ nanoparticles. The diameter of the QDs can be controlled by varying the number of the SILAR cycles. QDs with diameters in the range of 3-10 nm can be obtained after the reaction.

Step 4: A counterelectrode is prepared by coating a thin layer of Pt film on FTO glass.

Step 5: A solar cell is assembled by sandwiching the QD-coated electrode with the Pt counterelectrode using a surlyn spacer.

Step 6: An electrolyte is injected into predrilled holes on the counterelectrode. The holes are finally sealed with an epoxy. This finishes the fabrication of the QDSSC.

### Experiment 2

### Photovoltaic Measurements

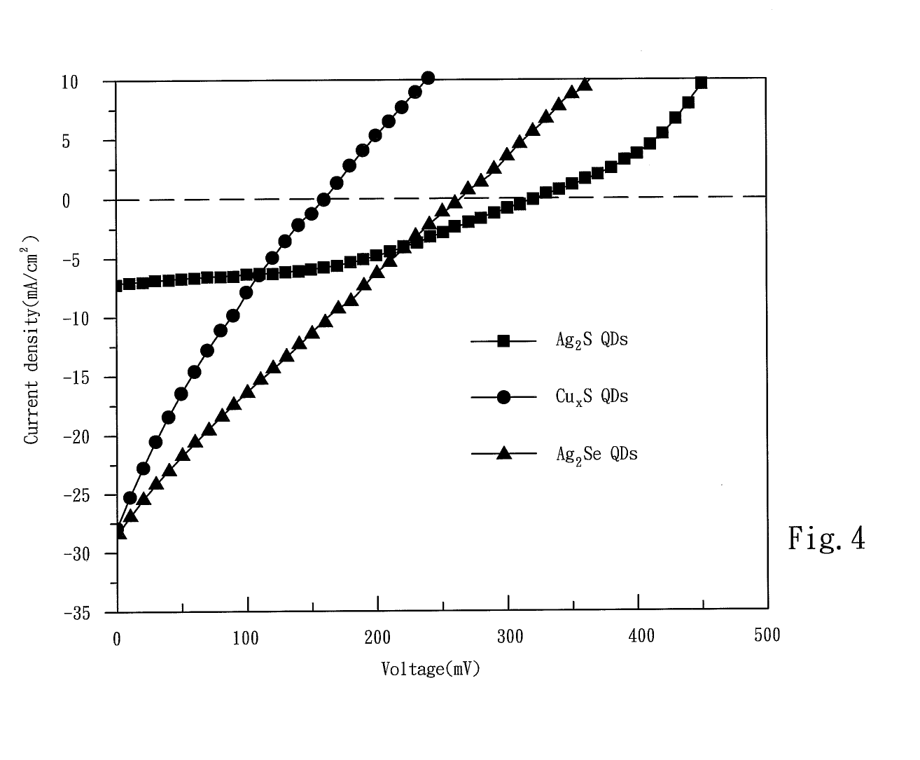

1. Photovoltaic performance: FIG. 4 shows the photocurrent-voltage curves of QDSSCs sensitized with Ag₂S, Ag₂Se and CuₓS QDs. The photovoltaic parameters are listed in Table 1.

TABLE 1

| | J_{sc} (mA | | | Efficiency |
|---|---|---|---|---|
| Sample | cm⁻²) | V_{oc} (V) | FF (%) | (%) |
| Ag₂S | 7.26 | 0.33 | 40.8 | 0.98 |
| Ag₂Se | 28.5 | 0.27 | 23.8 | 1.76 |
| CuₓS | 28.1 | 0.17 | 18.9 | 0.90 |

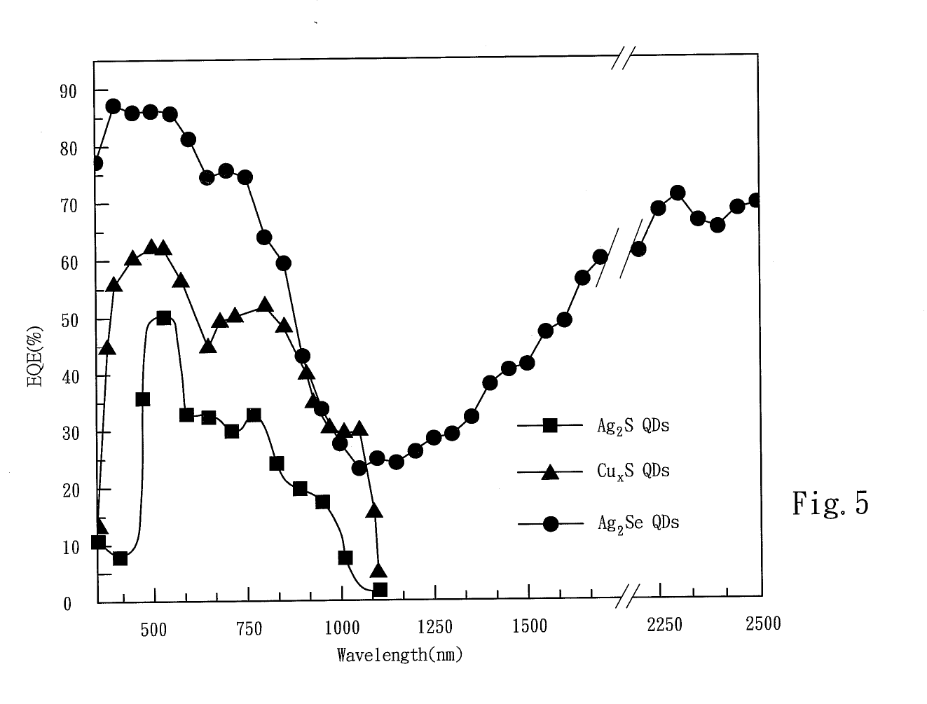

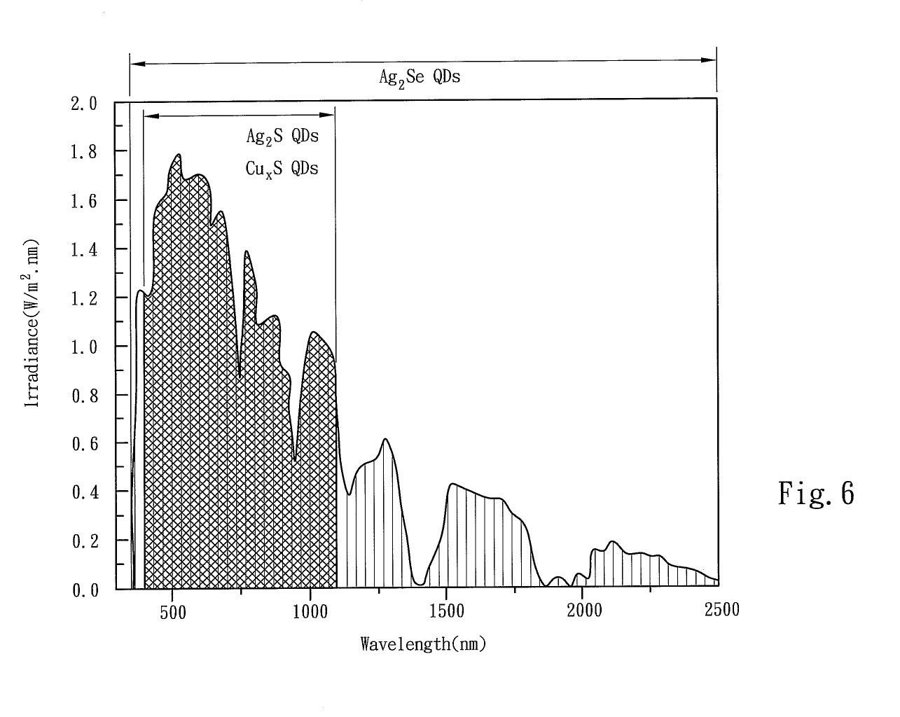

2. Quantum efficiency: FIG. 5 illustrates the quantum-efficiency (QE) spectra of QDSSCs sensitized with Ag₂S, Ag₂Se and CIO QDs. The Ag₂S and CuₓS spectra cover the spectra range of 350-1100 nm. The Ag₂Se spectrum covers the spectral range of 350-2500 nm. The quantum efficiency spectra are further supported by the absorption spectra in FIG. 6.

3. FIG. 6 displays the absorption spectra of various QDs. The solar power spectrum is also shown for comparison. It can be seen that the Ag₂S and CuₓS spectra covers the range of 350-1100 nm, i.e., UV, visible and IR. The cutoff of the QE spectra is at the wavelength about 1100 nm, which is equal to the wavelength of an optimal solar absorber. This indicates that Ag₂S and CuₓS QDs can be ideal high-efficiency absorbers for solar cells. The Ag₂Se QE spectrum exhibits an intriguing feature-it covers the full solar spectral range of 350-2500 nm, indicating that Ag₂Se can utilize the full solar power for energy conversion.

In summary, the Ag₂S and CuₓS QDs have broad photovoltaic ranges that cover the UV, visible and IR ranges. In addition, the QE spectra have a cutoff wavelength close to that of an optimal solar absorber. The Ag₂Se QDs have a photovoltaic range that covers the full solar spectrum of 350-2500 nm. A broad photovoltaic range means that the solar cell can convert a broader range of the incident solar power into electrical current, which results in a large photocurrent and high power conversion efficiency.

What is claimed is:

1. A quantum dot sensitized solar cell comprising an anode, a cathode and an electrolyte between the anode and the cathode, wherein the anode comprises:
a semiconductor electrode layer;
a plurality of quantum dots distributed within the semiconductor electrode layer, the quantum dots are made of a material selected from the group consisting of Ag₂S, Ag₂Se, CuₓS and CuₓSe.

2. The quantum dot sensitized solar cell of claim 1, wherein the semiconductor electrode layer is made of a material selected from the group consisting of TiO₂, N-doped TiO₂ and ZnO.

3. The quantum dot sensitized solar cell of claim 1, wherein a particle diameter of the quantum dots is smaller than 20 nm.

4. The quantum dot sensitized solar cell of claim 1, wherein the semiconductor electrode layer comprises a plurality of semiconductor nanoparticles, quantum dots are deposited on the surface of the semiconductor electrode.

5. The quantum dot sensitized solar cell of claim 1, wherein the semiconductor electrode layer comprises a plurality of semiconductor nanoparticles, quantum dots are coupled directly to the nanoparticle surface.

6. The quantum dot sensitized solar cell of claim 1, wherein the semiconductor electrode layer comprises a plurality of semiconductor nanoparticles, quantum dots are coupled to the semiconductor nanoparticles using a ligand linker.

7. A quantum dot sensitized solar cell (QDSSC) comprising an anode, a cathode and an electrolyte between the anode and the cathode, wherein the anode comprises:
a semiconductor electrode layer;
a plurality of quantum dots distributed within the semiconductor electrode layer, each of the quantum dots is a combination of a first element and a second element, the first element is made of a material selected from the group consisting of Ag₂S, Ag₂Se, CuₓS and CuₓSe, the second element is made of a material selected from the group consisting of CdS, CdSe, CdTe, In₂S₃, In₂Se₃, In₂Te₃, PbS, PbSe, PbTe, SnS, SnSe, SnTe, Sb₂S₃, Sb₂Se₃, AlN, AlP, AlAs, GaN, GaP, GaAs, GaSb, InN, InP, InAs, InSb, Si and Ge.

8. The quantum dot sensitized solar cell of claim 7, wherein the semiconductor electrode layer is made of a material selected from the group consisting of TiO₂, N-doped TiO₂ and ZnO.

9. The quantum dot sensitized solar cell of claim 7, wherein a particle diameter of the quantum dots is smaller than 20 nm.

10. The quantum dot sensitized solar cell of claim 7, wherein the first element and the second element is a core-shell structure, and the first element is the core material, the second element is the shell material.

11. The quantum dot sensitized solar cell of claim 7, wherein the first element and the second element is a core-shell structure, and the first element is the shell material, the second element is the core material.

12. The quantum dot sensitized solar cell of claim 7, wherein the semiconductor electrode layer comprises a plurality of semiconductor nanoparticles, quantum dots are deposited on the surface of the semiconductor electrode.

13. The quantum dot sensitized solar cell of claim 7, wherein the semiconductor electrode layer comprises a plurality of semiconductor nanoparticles, quantum dots are coupled to the semiconductor nanoparticles using a ligand linker.
